(19) United States
(12) Patent Application Publication
(10) Pub. No.: US 2013/0167913 A1
(43) Pub. Date: Jul. 4, 2013

(54) METHOD OF PRODUCING ANODE MATERIAL AND THE ANODE MATERIALS THEREOF

(71) Applicants: Chi-Young LEE, Hsinchu City (TW); Hsiao-Ping Liu, Hsinchu City (TW); Hsin-Tien Chiu, Hsinchu City (TW); Yen-Ju Wei, Hsinchu City (TW)

(72) Inventors: Chi-Young LEE, Hsinchu City (TW); Hsiao-Ping Liu, Hsinchu City (TW); Hsin-Tien Chiu, Hsinchu City (TW); Yen-Ju Wei, Hsinchu City (TW)

(73) Assignee: NATIONAL TSING HUA UNIVERSITY, Hsinchu (TW)

(21) Appl. No.: 13/549,972

(22) Filed: Jul. 16, 2012

(30) Foreign Application Priority Data
Jan. 2, 2012 (TW) 101100057

(51) Int. Cl. H01L 31/0216; B05D 5/12

(52) U.S. Cl. 136/252; 427/74

(57) ABSTRACT

The present invention provides a method of producing anode material, and the steps are as follows: TiO₂ and NaOH are in the hydrothermal reaction to generate a fibered precursor; acid pickling the fibered precursor to generate a fibered sodium hydroxo titanate (H₂Ti₃O₇.5H₂O); disposing the fibered sodium hydroxo titanate on a membrane to dry, and thus to generate a flexible sodium hydroxo titanate membrane; and the flexible sodium hydroxotitanate membrane is reacted with NH₃ flow to generate a titanium oxynitride membrane.

### CROSS-REFERENCE TO RELATED APPLICATIONS

This Non-provisional application claims priority under 35 U.S.C. §119(a) on Patent Application No(s). 101100057 filed in Taiwan, Republic of China Jan. 2, 2012, the entire contents of which are hereby incorporated by reference.

### FIELD OF THE INVENTION

This invention relates to a method of producing anode material, and, more particularly, a method of producing flexible anode material with high electric conductivity.

### BACKGROUND OF THE INVENTION

Energy and environment are two major issues of the world economics in the 21^{st} century. The energy technology is an important industry in the global markets and the solar energy technology play a very important role. In solar energy technology, solar cell research and development are the fastest growing and most dynamic research areas in recent years, and the annual growth rate of solar energy technology is up to 30%, even more than the growth rate of IT industry. However, the applications of large-scale promotion are limited due to the complex process of traditional silicon solar cells and high production costs.

In recent years, the conversion efficiency of solar cells is increased due to the development of nanotechnology and advanced materials. Dye sensitized solar cells (DSSC) is developed by Prof. Grazel's team in 1998. They used the porous titanium dioxide nano-particle film production to produce the whole solid-state the DSSC and reached the single shade of the photoelectric conversion efficiency up to 13%, which becomes the most potential technique for commercialization. DSSC has the advantages such as low cost, easy fabrication, high photoelectric conversion efficiency, and short energy recovery time and is considered as the most powerful alternative for silicon solar cells.

DSSC is mainly composed of the transparent conductive substrate, porous nano-crystalline films of titanium dioxide (TiO₂), dye, electrolyte and the electrodes. The substrate types of DSSC can be divided into rigid DSSC and flexible DSSC. Flexible electrode has the advantages of low cost, light weight, free deformation, easy to carry and easy processing with large area. To produce the flexible light anodic titanium oxide film can help to resolve the problems of producing flexible DSSC.

Traditional conductive film is mainly composed of metallic materials, polymer materials, PET polymer substrate with ITO sputtering, or graphite. Among the materials, the metal material has the disadvantages of high costs and the impatience of the acidity problem; the polymer materials, PET-plated oxide and graphite have the advantages of low cost, acid-alkali resistance, but are not high-temperature resistance. Among all the materials, there are different disadvantages whether in features, complexity or cost of the manufacturing process.

Taking the conductive glass electrodes FTO for example, FIG. 1a shows the cyclic voltammetry curves of learned conductive glass electrode. The electrochemical effective surface area (ESA) has an average value of 0.11 cm². FIG. 1b shows the corresponding current of FIG. 1a in unit time. The slope is 0.1595.

Therefore, in this invention, the applicant provides a new kind of anode material to solve this problem by the method of producing The titanium oxynitride membrane.

### SUMMARY OF THE INVENTION

The invention provides a method of producing anode material, and the steps are as follows:
(a) TiO₂ and NaOH are processed by hydrothermal reaction to generate a fibered precursor.
(b) The fibered precursor is acid pickled to generate a fibered sodium hydroxo titanate (H₂Ti₃O₇.5H₂O).
(c) The fibered H₂Ti₃O₇.5H₂O is disposed on a membrane for drying to generate a flexible H₂Ti₃O₇.5H₂O membrane.
(d) The flexible H₂Ti₃O₇.5H₂O membrane is provided to react with NH₃ flow to generate a titanium oxynitride membrane.

The invention also provides an anode material by the method of producing anode material. The anode material includes an anode body composed of titanium oxynitride and a membrane composed of nano-materials.

Except the advantage of high electric conductivity and high charge efficiency, the titanium oxynitride membrane also can be applied to supercapacitor as an energy storage with high efficiency. Because the titanium oxynitride membrane can charge or discharge rapidly, it can be applied to the apparatus which can start immediately, such as a car engine, but not limited herein.

The titanium oxynitride membrane by the method of producing anode material includes the advantages of low cost, acid-alkali resistance, flexible, high electric conductivity and high-temperature resistance. Therefore, the titanium oxynitride membrane can be applied to flexible DSSC, and further to resolve the problems of prior art.

These and other features, aspects and advantages of the present disclosure will become better understood with regard to the following description, appended claims, and accompanying drawings.

### BRIEF DESCRIPTION OF THE DRAWINGS

FIG. 1a shows the cyclic voltammetry curves of learned conductive glass electrode (FTO, fluorine-doped tin oxide) of the prior art.

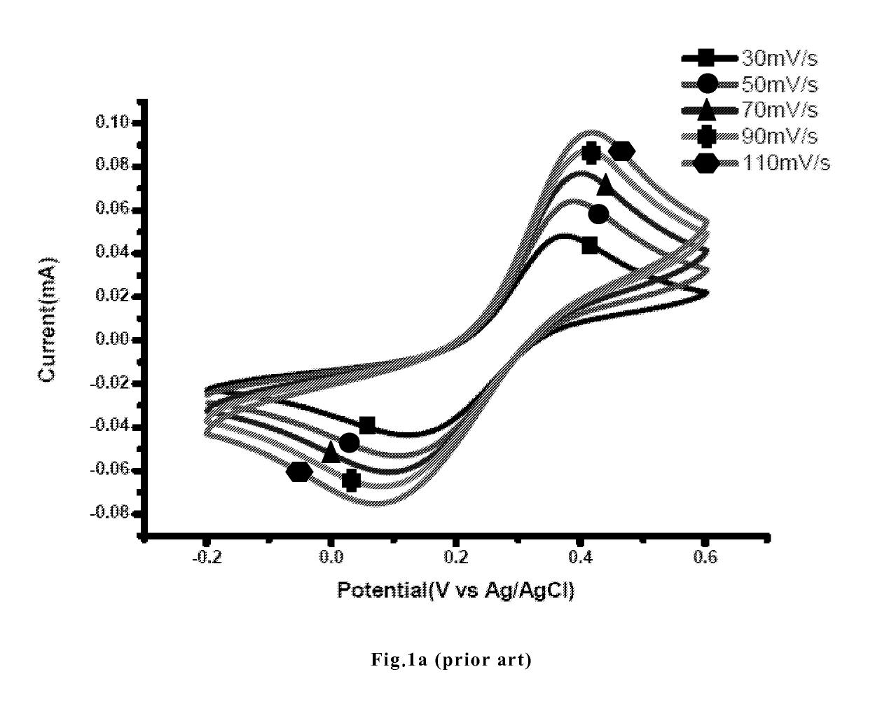

FIG. 1b shows the corresponding current of FIG. 1a in unit time. FIG. 1b shows responses of reduction peak current to square root of scan rate of the electrode (FIG. 1a).

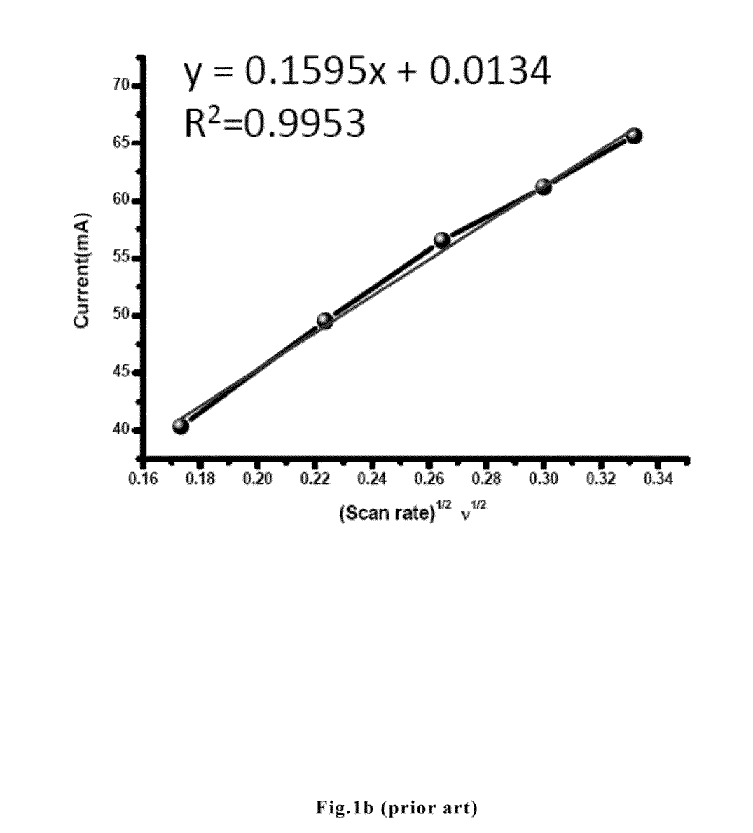

FIG. 2 shows a flow chart of the method of producing anode material in the invention.

Table 1 shows the experiment data of the resistivities of titanium oxynitride membranes by the method of producing anode material in the invention.

FIG. 3 shows an analysis drawing of the flexible H₂Ti₃O₇.5H₂O membrane by X-ray Diffractometer (XRD).

FIG. 4 shows a picture of the flexible H₂Ti₃O₇.5H₂O membrane by electron microscope (SEM). FIG. 4(a) is magnified 50,000 times, FIG. 4(b) is magnified 10,000 times, and FIG. 4(c) is magnified 5,000 times.

FIG. 5 shows an analysis drawing of the titanium oxynitride membrane by X-ray Diffractometer (XRD).

FIG. 6 shows a picture of the titanium oxynitride membrane by electron microscope (SEM). FIG. 6(a) is magnified 50,000 times, FIG. 6(b) is magnified 10,000 times, and FIG. 6(c) is magnified 5,000 times.

FIG. 7a shows cyclic voltammetry curves of the titanium oxynitride membrane at 850° C. in step (d).

FIG. 7b shows the corresponding current of FIG. 7a in unit time. FIG. 7b shows responses of reduction peak current to square root of scan rate of the electrode (FIG. 7a).

FIG. 8a shows cyclic voltammetry curves of the titanium oxynitride membrane at 950° C. in step (d).

FIG. 8b shows the corresponding current of FIG. 8a in unit time. FIG. 8b shows responses of reduction peak current to square root of scan rate of the electrode (FIG. 8a).

### DETAILED DESCRIPTION OF THE INVENTION

For clarity of disclosure, and not by way of limitation, the detailed description of the invention is divided into the subsections that follow.

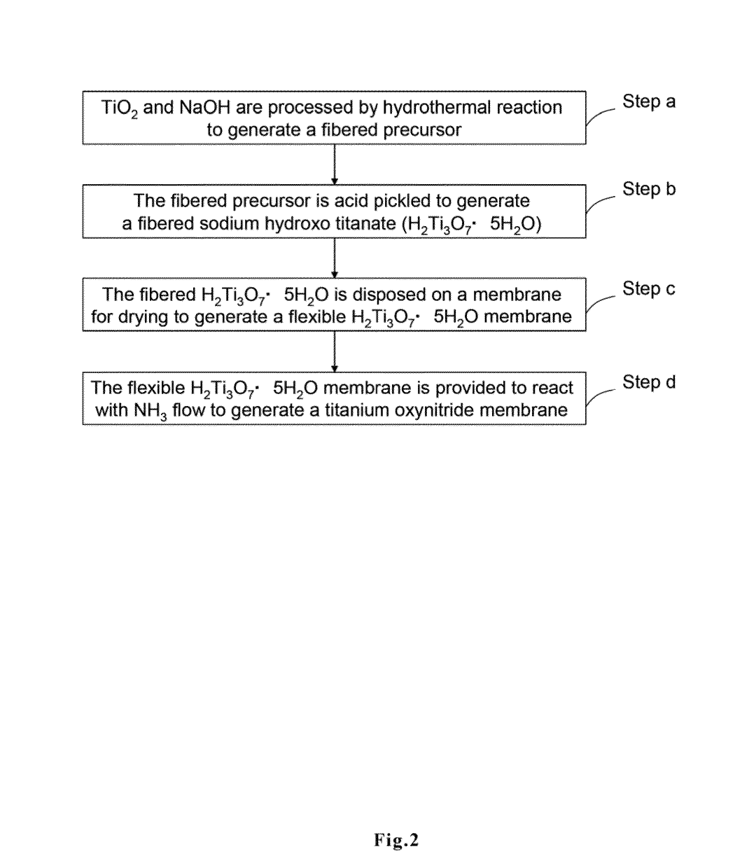

FIG. 2 shows a flow chart of the method of producing anode material in the invention. The steps are as follows:

(a) TiO₂ and NaOH are processed by hydrothermal reaction to generate a fibered precursor.

In an embodiment, the molarity of NaOH is 5M˜15M. The molarity of 5M is preferred, but not limited herein. TiO₂ and NaOH are disposed at about 100° C. ˜200° C. by hydrothermal reaction for about 12˜72 hours. The temperature of 120° C. and the reaction time of 48 hours are preferred, but not limited herein.

(b) The fibered precursor is acid pickled to generate a fibered sodium hydroxo titanate (H₂Ti₃O₇.5H₂O).

In an embodiment, the fibered precursor is acid pickled with HCl, but not limited herein. The fibered H₂Ti₃O₇.5H₂O can be mixed with H₂O, and well mixed by an ultrasonic vibrator or a stirring-magnet to form a solution, but not limited herein.

(c) The fibered H₂Ti₃O₇.5H₂O is disposed on a membrane for drying to generate a flexible H₂Ti₃O₇.5H₂O membrane.

In an embodiment, the membrane is composed of polymer-materials, such as nano-materials, but not limited herein. In step (c), the fibered H₂Ti₃O₇.5H₂O is filtered by low pressure, then is disposed in an oven at about 45° C.˜100° C. for drying. The temperature of 50° C. is preferred, but not limited herein.

At present, the flexible H₂Ti₃O₇.5H₂O membrane is flexible, and the length of the flexible H₂Ti₃O₇.5H₂O membrane is 0.5˜5 cm, and the thickness of the flexible H₂Ti₃O₇.5H₂O membrane is 20˜100 μm. The length of 2 cm and the thickness of 50˜70 μm are preferred, but not limited herein. In addition, the resistance of the flexible H₂Ti₃O₇.5H₂O membrane is still too large to conduct electricity well.

(d) The flexible H₂Ti₃O₇.5H₂O membrane is provided to react with NH₃ flow to generate a titanium oxynitride membrane.

In an embodiment, the flow rate of the NH₃ is 20˜110 ml/min. The flow rate of 100 ml/min is preferred, but not limited herein. In step (d), the flexible H₂Ti₃O₇.5H₂O membrane reacts with NH₃ at 500° C.˜1000° C. for 3˜12 hours. The temperature of 750° C. and the reaction time of 10 hours are preferred, but not limited herein.

At present, the resistance of the titanium oxynitride membrane is about 45Ω˜75Ω. Compared with the resistance of the flexible H₂Ti₃O₇.5H₂O membrane in step (c), the resistance of the titanium oxynitride membrane in step (d) is lower and includes higher electric conduction. The resistance of 50˜70Ω is preferred, but not limited herein.

Table 1 shows the experiment data of the titanium oxynitride membrane by the method of producing anode material in the invention. The resistance of the titanium oxynitride membrane changes with reaction time of NH₃ and temperature. The resistivity of the titanium oxynitride membrane is 6.02×10⁻² with reaction time of NH₃ for 10 hours and the temperature of 750° C. The resistivity of the titanium oxynitride membrane is 5.529×10⁻³ with reaction time of NH₃ for 6 hours and the temperature of 950° C. The resistivity of the titanium oxynitride membrane is 3.18×10⁻³ with reaction time of NH₃ for 10 hours and the temperature of 950° C.

| condition | resistivity (Ohm · cm) |
|---|---|
| 750° C., 10 hours | 6.02 × 10⁻² |
| 950° C., 06 hours | 5.529 × 10⁻³ |
| 950° C., 10 hours | 3.18 × 10⁻³ |

The invention also provides an anode material by the method of producing anode material. The anode material includes an anode body composed of titanium oxynitride and a membrane composed of nano-materials. The membrane is connected with the anode body. The titanium oxynitride of the anode material is used to adsorb Ruthenium complex for photo-electricity conversion.

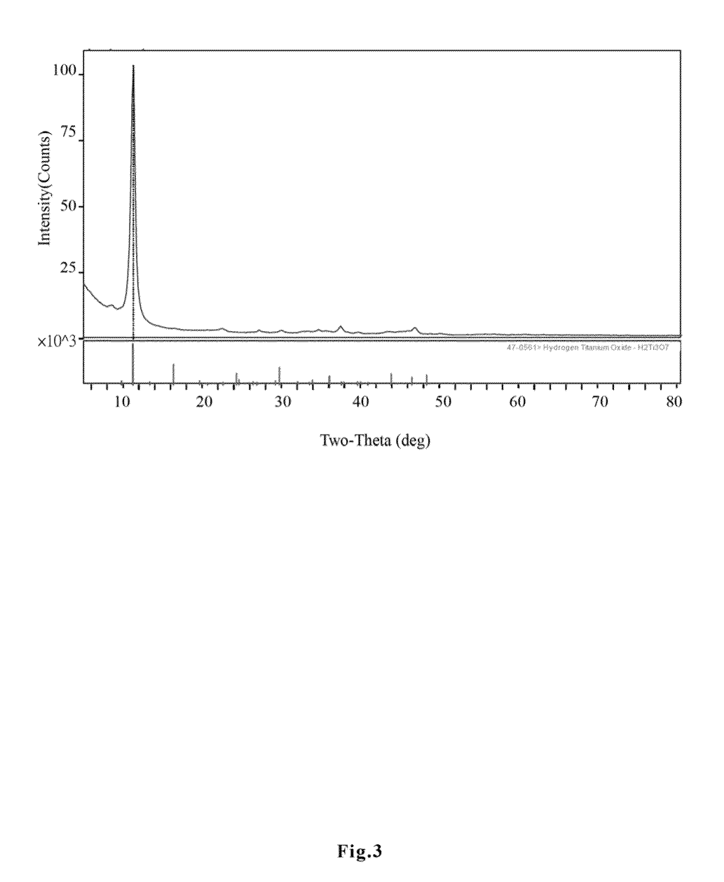

FIG. 3 shows an analysis drawing of the flexible H₂Ti₃O₇.5H₂O membrane by X-ray Diffractometer (XRD). The crystalling phase of the flexible H₂Ti₃O₇.5H₂O membrane is hydrogen titanium oxide (JCPDS:47-0561).

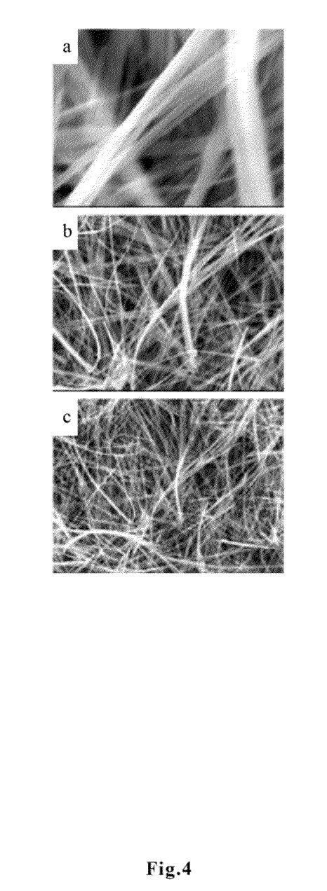

FIG. 4 shows a picture of the flexible H₂Ti₃O₇.5H₂O membrane by electron microscope (SEM). FIG. 4(a) is magnified 50,000 times, FIG. 4(b) is magnified 10,000 times, and FIG. 4(c) is magnified 5,000 times. The flexible H₂Ti₃O₇.5H₂O membrane is composed of long fibers, and the diameter of the long fibers is about 100 nm˜200 nm.

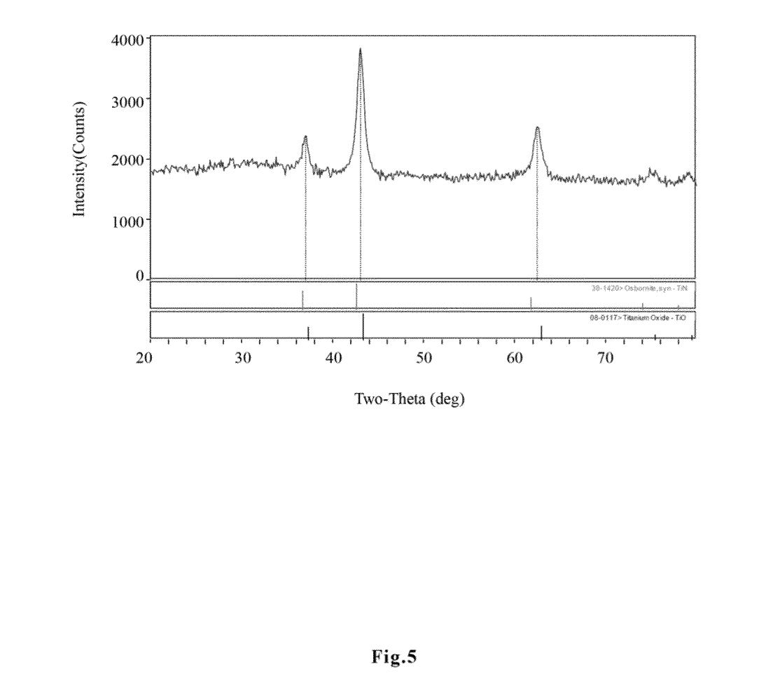

FIG. 5 shows an analysis drawing of the titanium oxynitride membrane by X-ray Diffractometer (XRD). The crystal lattice spacing of the titanium oxynitride membrane is between TiO (JCPDS:08-0117) and TIN (JCPDS:38-1420), so the structure is derived from TiOₓN_{y}.

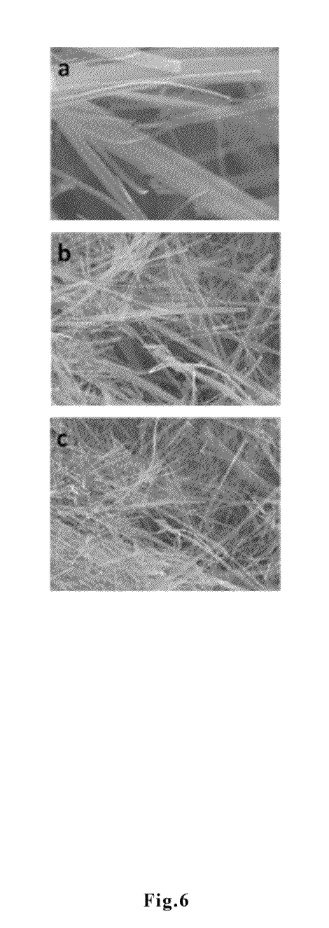

FIG. 6 shows a picture of the titanium oxynitride membrane by electron microscope (SEM). FIG. 6(a) is magnified 50,000 times, FIG. 6(b) is magnified 10,000 times, and FIG. 6(c) is magnified 5,000 times. The titanium oxynitride membrane is also composed of long fibers, and the diameter of the long fibers is also about 100 nm˜200 nm. Compared with the long fibers of the flexible H₂Ti₃O₇.5H₂O membrane, the length of the long fibers of the titanium oxynitride membrane is shorter, it's about 10 μm.

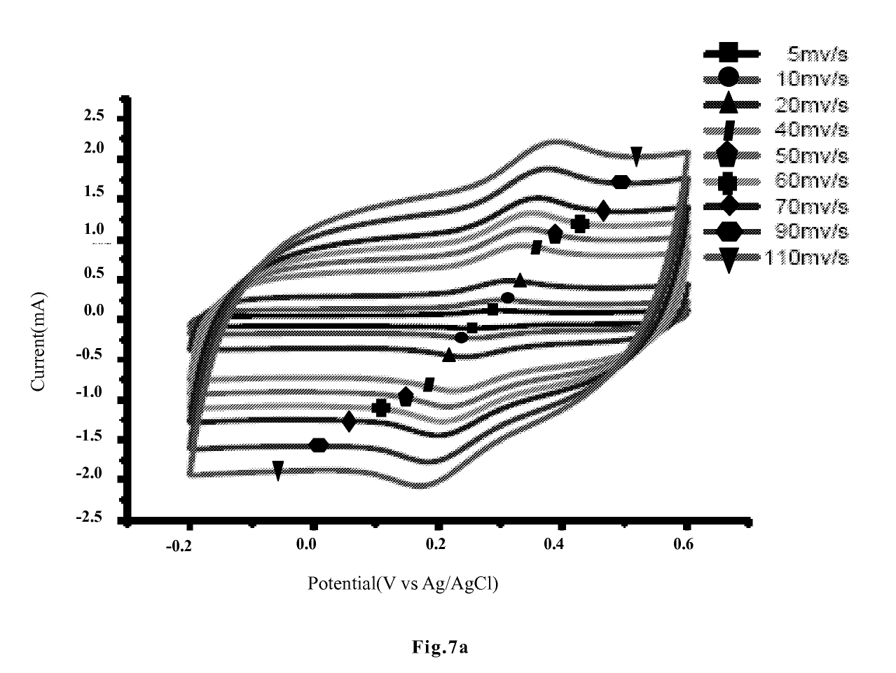

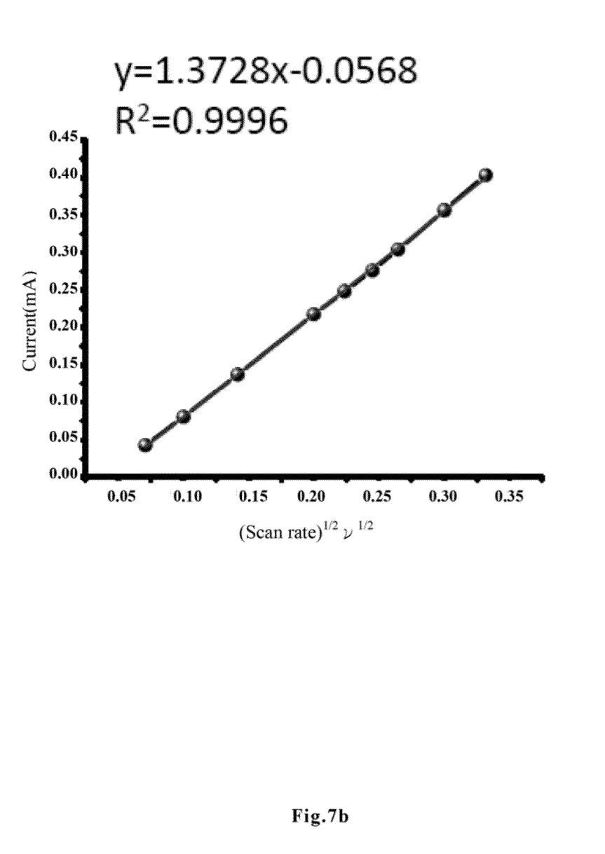

FIG. 7a shows cyclic voltammetry curves of the titanium oxynitride membrane at 850° C. in step (d). The electrochemical effective surface area (ESA) has an average value of 0.96 cm². FIG. 7b shows the corresponding current of FIG. 7a in unit time. The slope is 1.3728.

The ESA and the slope of the titanium oxynitride membrane are larger than the ESA and the slope of conventional FTO. It means that the anode material by the method of producing anode material in the invention includes higher sensitivity, so the titanium oxynitride membrane includes better efficiency.

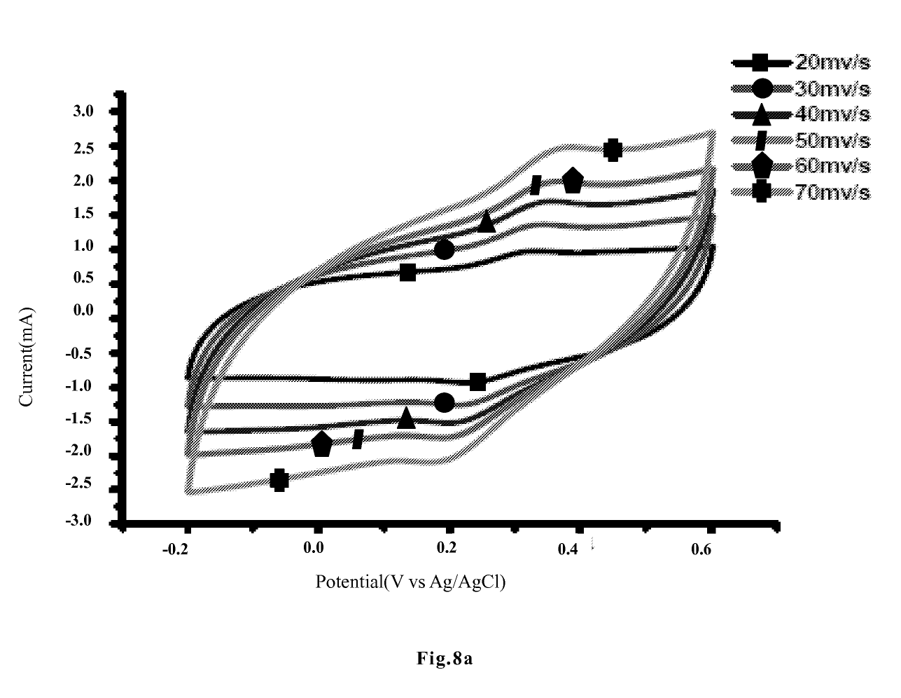

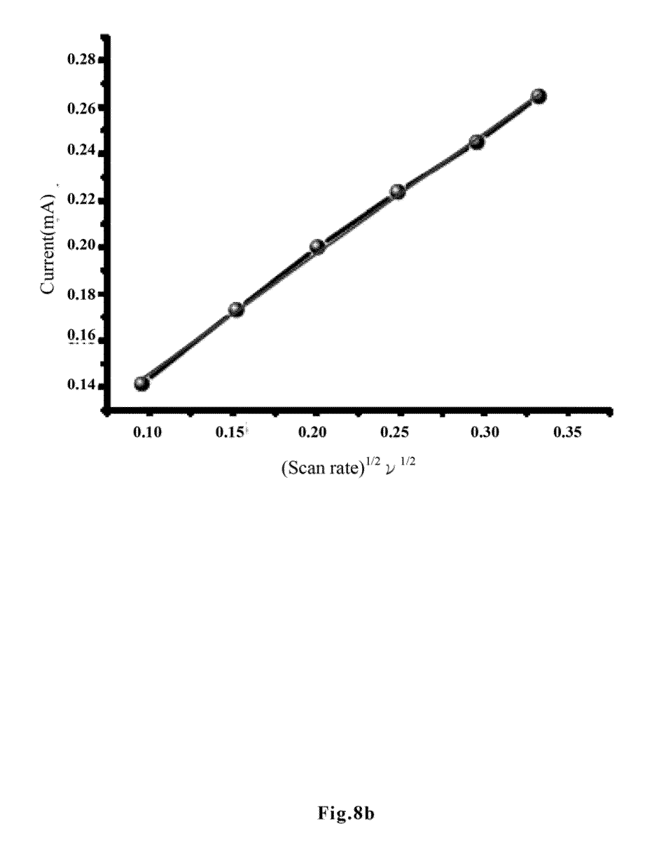

FIG. 8a shows cyclic voltammetry curves of the titanium oxynitride membrane at 950° C. in step (d). The electrochemical effective surface area (ESA) has an average value of 0.36 cm². FIG. 8b shows the corresponding current of FIG. 8a in unit time. The slope is 0.5148.

The ESA and the slope of the titanium oxynitride membrane are larger than the ESA and the slope of conventional FTO. It means that the anode material by the method of producing anode material in the invention includes higher sensitivity, so the titanium oxynitride membrane includes better efficiency.

Except the advantage of high electric conduction and high charge efficiency, the titanium oxynitride membrane also can be applied to supercapacitor as an energy storage with high efficiency. Because the titanium oxynitride membrane can charge or discharge rapidly, it can be applied to the apparatus which can start immediately, such as a car engine, but not limited herein.

The titanium oxynitride membrane by the method of producing anode material includes the advantages of low cost, acid-alkali resistance, flexible, high electric conductivity and high-temperature resistance. Therefore, the titanium oxynitride membrane can be applied to flexible DSSC, and further to resolve the problems of prior art.

Although the present invention has been described in terms of specific exemplary embodiments and examples, it will be appreciated that the embodiments disclosed herein are for illustrative purposes only and various modifications and alterations might be made by those skilled in the art without departing from the spirit and scope of the invention as set forth in the following claims.

What is claimed is:

1. A method of producing anode material, comprising the steps of:
(a) TiO₂ and NaOH being processed by hydrothermal reaction to generate a fibered precursor;
(b) acid pickling the fibered precursor to generate a fibered sodium hydroxo titanate (H₂Ti₃O₇.5H₂O);
(c) disposing the fibered sodium hydroxo titanate on a membrane for drying to generate a flexible sodium hydroxo titanate membrane; and
(d) providing the flexible sodium hydroxo titanate membrane to react with NH₃ flow to generate a titanium oxynitride membrane.

2. The method of producing anode material according to claim 1, wherein in step (a), the molarity of NaOH is 5M˜15M.

3. The method of producing anode material according to claim 1, wherein in step (a), TiO₂ and NaOH are disposed at 100° C.˜200° C. by hydrothermal reaction for 12˜72 hours.

4. The method of producing anode material according to claim 1, wherein in step (b), the fibered precursor is acid pickled with HCl.

5. The method of producing anode material according to claim 1, wherein in step (c), the fibered sodium hydroxo titanate is mixed with H₂O to form a solution.

6. The method of producing anode material according to claim 1, wherein in step (c), the membrane is composed of nano-materials.

7. The method of producing anode material according to claim 1, wherein in step (c), the fibered sodium hydroxo titanate and the membrane are disposed in an oven at 45° C.˜100° C. for drying.

8. The method of producing anode material according to claim 1, wherein in step (c), the length of the flexible sodium hydroxo titanate membrane is 0.5˜5 cm, and the thickness of the flexible sodium hydroxo titanate membrane is 20-100 μm.

9. The method of producing anode material according to claim 1, wherein in step (d), the flow rate of the NH₃ is 20˜110 ml/min.

10. The method of producing anode material according to claim 1, wherein in step (d), the flexible sodium hydroxo titanate membrane reacts with NH₃ at 500° C.˜1000° C. for 3˜12 hours.

11. The method of producing anode material according to claim 1, wherein in step (d), the resistance of the titanium oxynitride membrane is 45Ω˜75Ω.

12. The method of producing anode material according to claim 1, wherein in step (d), the titanium oxynitride membrane is flexible.

13. The method of producing anode material according to claim 1, wherein in step (d), the titanium oxynitride membrane is acid-alkali resistant.

14. The method of producing anode material according to claim 1, wherein in step (d), the titanium oxynitride membrane is high-temperature resistant.

15. An anode material, comprising:
an anode body, composed of titanium oxynitride; and
membrane, connected with the anode body.

16. The anode material according to claim 15, wherein the membrane is composed of nano-materials.

17. The anode material according to claim 15, wherein the titanium oxynitride is used to adsorb Ruthenium complex.

18. The anode material according to claim 15, wherein the anode material is flexible.

19. The anode material according to claim 15, wherein the anode material is acid-alkali resistant.

20. The anode material according to claim 15, wherein the anode material is high-temperature resistant.
